(19) United States
(12) Patent Application Publication
(10) Pub. No.: US 2006/0097341 A1
(43) Pub. Date: May 11, 2006

(54) Forming phase change memory cell with microtrenches

(76) Inventors: Fabio Pellizzer, Follina (TV) (IT); Charles H. Dennison, San Jose, CA (US)

Correspondence Address: TROP PRUNER & HU, PC, 8554 KATY FREEWAY, SUITE 100, HOUSTON, TX, 77024, US

(21) Appl. No.: 10/982,295

(22) Filed: Nov. 5, 2004

(51) Int. Cl. H01L 29/00; H01L 21/477

(52) U.S. Cl. 257/528; 257/529; 438/381; 438/799

(57) ABSTRACT

A semiconductor substrate is covered by a dielectric region. The dielectric region accommodates a memory element and a selection element forming a phase change memory cell. The memory element is formed by a resistive element and by a storage region of a phase change material extending on and in contact with the resistive element at a contact area. The selection element is formed by a switching region of chalcogenic material embedded in the dielectric region and belonging to a stack extending on the resistive element and including also the storage region. A mold region extends on top of the resistive element and delimits a trench having a substantially elongated shape. At least one portion of the storage region extends in the trench and defines a phase change memory portion over the contact area.

### BACKGROUND

The present invention relates to phase change memories.

Phase change memories use a class of materials that have the property of switching between two phases having distinct electrical characteristics, associated with two different crystallographic structures of the material and variations thereof, such as an amorphous, disordered phase and a crystalline or polycrystalline, ordered phase. The two phases are hence associated to resistivities of considerably different values where the more disordered phases are higher in resistivity and the crystalline are lower in resistivity.

Currently, the alloys of elements of group VI of the periodic table, such as Te or Se, referred to as chalcogenides or chalcogenic materials, can be used advantageously in phase change memory cells. The currently most promising chalcogenide is formed from an alloy of Ge, Sb and Te (Ge₂Sb₂Te₅), which is now widely used for storing information on overwritable disks and has also been proposed for mass storage.

In the chalcogenides, the resistivity varies by two or more orders of magnitude when the material passes from the amorphous (more resistive) phase to the crystalline (more conductive) phase, and vice versa.

Phase change can be obtained by locally increasing the temperature. Below 150° C., both the phases are stable. Starting from an amorphous state, and raising the temperature above 200° C., there is a rapid nucleation of the crystallites and, if the material is kept at the crystallization temperature for a sufficiently long time, it undergoes a phase change and becomes crystalline. To bring the chalcogenide back to the amorphous state it is necessary to raise the temperature above the melting temperature (approximately 600° C.) and then rapidly cool off the chalcogenide. Memory devices exploiting the properties of chalcogenic material are called phase change memories.

### BRIEF DESCRIPTION OF THE DRAWINGS

For the understanding of the present invention, preferred embodiments thereof are now described, purely as non-limitative examples, with reference to the enclosed drawings, wherein:

FIG. 1 is a block diagram of a phase change memory according to one embodiment of the present invention;

FIG. 2 illustrates the characteristic current-voltage of an ovonic threshold switch.

FIGS. 3-7 show cross-sections through a semiconductor wafer according to a first embodiment of the invention, in successive manufacturing steps;

FIG. 8 is a cross-section taken generally along the line 8-8 in FIG. 10;

FIG. 9 is a cross-section of the wafer of FIG. 8, taken generally along the line 9-9 in FIG. 10;

FIG. 10 is a top view of the wafer of FIGS. 8 and 9;

FIGS. 11-14 show cross-sections through a semiconductor wafer according to a first embodiment of the invention, in successive manufacturing steps;

FIG. 15 is a cross-section of the wafer of FIGS. 16 and 17, taken generally along the line 15-15 in FIG. 17;

FIG. 16 is a cross-section of the wafer of FIG. 15, taken generally along the line 16-16 in FIG. 17;

FIG. 17 is a top view of the wafer of FIGS. 15 and 16;

FIG. 18 is a cross-section of the wafer according to a second embodiment, in a final manufacturing step, taken generally along the line 18-18 in FIG. 19;

FIG. 19 is a top plan view of the wafer of FIG. 18;

FIG. 20 is a cross-section of a wafer according to a third embodiment, in subsequent manufacturing steps taken generally along the line 20-20 in FIG. 22;

FIG. 21 is a cross-section of the wafer of FIG. 20, taken generally along the line 21-21 in FIG. 22;

FIG. 22 is a plan view of the wafer of FIGS. 20 and 21;

FIG. 23 is a cross-section of a wafer according to another embodiment, in subsequent manufacturing steps, taken generally along the line 23-23 in FIG. 22;

FIGS. 24-26 show cross-section of a wafer according to another embodiment, in subsequent steps;

FIG. 27 show the cross-section of the wafer of FIG. 26, taken in a perpendicular direction;

FIG. 28 is a cross-section of another embodiment, taken generally along the line 28-28 in FIG. 25; and

FIG. 29 is a top plan view of the wafer of FIG. 28.

### DETAILED DESCRIPTION

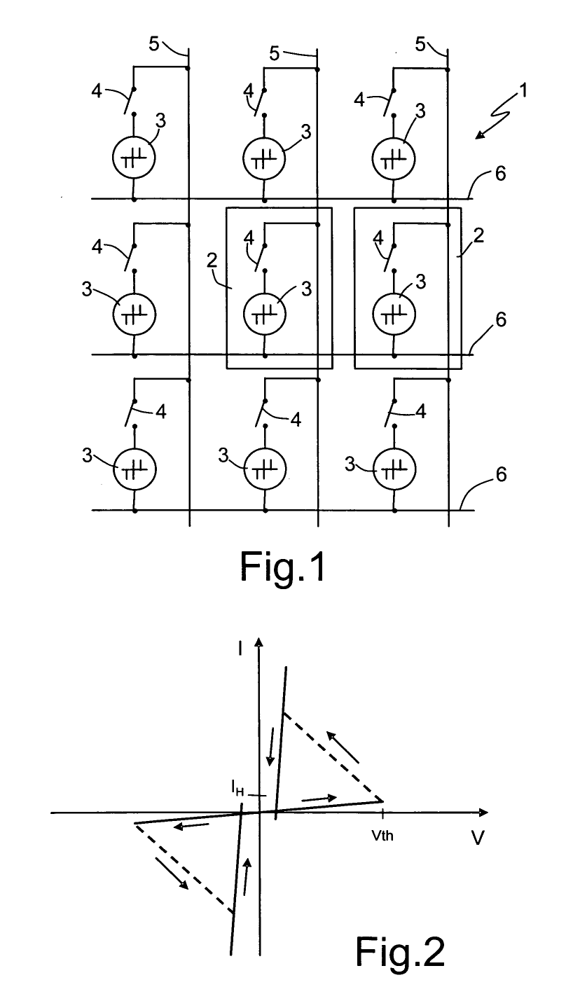

In a phase change memory including chalcogenic elements as storage elements, memory cells form an array and can be arranged in rows and columns, as shown in FIG. 1. The memory array 1 of FIG. 1 comprises a plurality of memory cells 2, each including a memory element 3 of the phase change type and a selection element 4. The memory cells 2 are interposed at cross-points of rows 6 (also called word lines) and columns 5 (also called bit lines).

In each memory cell 2, the memory element 3 has a first terminal connected to a bitline 5 and a second terminal connected to a first terminal of a selection element 4. The selection element 4 has a second terminal connected to a row 6.

The selection element 4 may be implemented by any switching device, such as a PN diode, a bipolar junction transistor or a MOS transistor, or by another thin film device such as an Ovonic Threshold Switch (OTS).

A binary memory may be formed by an array of cells including a selection element called “ovonic threshold switch” (also referred to as an OTS hereinafter), connected in series with a memory element called “ovonic memory switch” (OMS). The OTS and the OMS may be formed adjacent to each other on an insulating substrate and may be connected to each other through a conducting strip. Each cell is coupled between a row and a column of a memory array and the OTS has the same function as the selection element 4 in FIG. 1. Both the OTS and the OMS are formed by a semiconductor chalcogenic material and both show threshold switching when driven above their threshold voltage. The difference is that OMS can change its structural state (from amorphous to crystalline and vice versa), while OTS always retains its high impedance at low fields.

An ovonic threshold switch may have the characteristics shown in FIG. 2. An OTS has a high resistance for voltages below a threshold value Vth; when the applied voltage exceeds the threshold value Vth, the switch begins to conduct at a substantial constant voltage and presents a low impedance. When the current through the OTS falls below a holding current I_{H}, the OTS goes back to his high-impedance condition. This behavior may be symmetrical and can occur also for negative voltages and currents.

The OTS and the OMS may have substantially different high resistances. The OTS may have a higher resistance than the amorphous OMS. In such case, when a memory cell is to be read, a voltage drop is applied to the cell voltage. That drop is not sufficient to trigger both the OTS and the OMS when the latter is in its high resistance condition (associated with a digital “0” state), but is sufficient to drive the OTS in its (dynamic) low resistance condition when the OMS is already in its (stable) low resistance condition (associated with a digital “1” state).

From an electrical point of view, the crystallization temperature and the melting temperature are obtained by causing an electric current to flow through the memory element and resistive electrode in contact or close proximity with the chalcogenic material, thus heating the chalcogenic material by Joule effect in the electrode and by power in the chalcogenic material iteself.

In particular, a voltage/current pulse of a suitable length (corresponding to the crystallization time) and amplitude (corresponding to the crystallization temperature) may be applied in order to make the chalcogenic material crystallize. In this condition, the chalcogenic material changes its state and switches to a low resistivity state (also called the set state).

Vice versa, in order to bring the material to the high resistivity state (also called reset state), a voltage/current pulse of suitable duration and amplitude (corresponding to the melting temperature) may be applied to cause the chalcogenic material to melt, followed by terminating the pulse with a fast terminating edge rate, thus cooling it down rapidly and quenching it in the amorphous phase.

To reduce the amount of current needed to cause the chalcogenic material to change its state, a heater may be formed by a wall structure obtained by depositing a suitable resistive material. Furthermore, the chalcogenic material may include a thin portion extending transversely to the wall structure to obtain a small contact area. Here, the selection element is implemented by a junction diode formed in a semiconductor substrate just below the memory element.

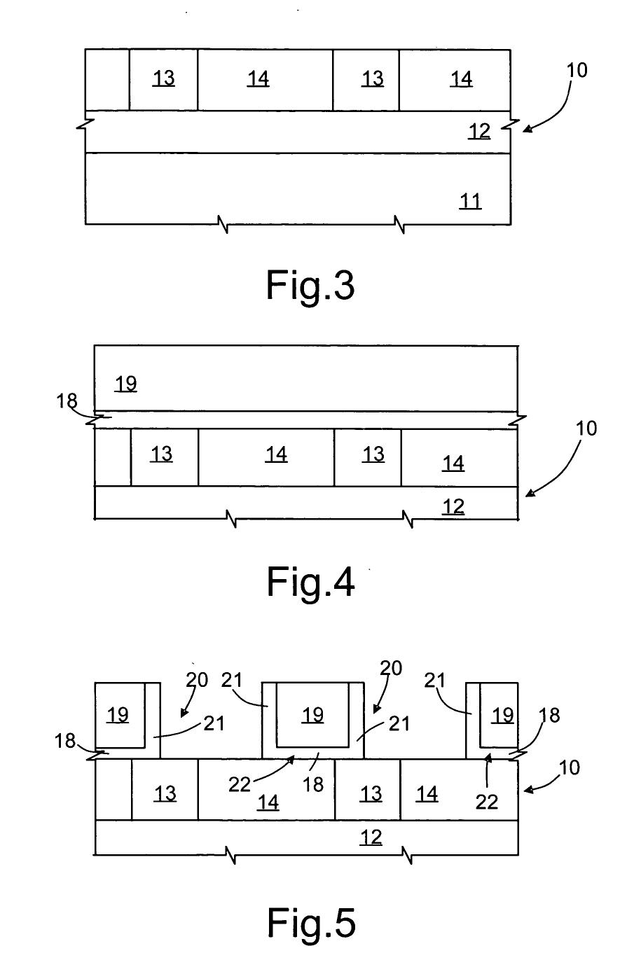

Referring to FIG. 3, a wafer 10 may include a substrate 11 of semiconductor material, e.g. silicon. The wafer 10 is covered by a first insulating layer 12. Row lines 13, e.g. of copper, are formed on top of the first insulating layer 12, insulated from each other by a first dielectric layer 14. Preferably, the row lines 13 (corresponding to the row lines 6 of FIG. 1) are formed by first depositing the first dielectric layer 14, then removing the dielectric material where the row lines 13 are to be formed, and then filling the trenches so obtained with copper. Any excess copper is then removed from the surface of the wafer 10 by chemical mechanical polishing (CMP) in a “damascene” process.

Thereafter, as shown in FIG. 4, an encapsulating structure is formed by depositing, in sequence, a first nitride layer 18 and a first oxide layer 19, planarizing the first oxide layer 19 by CMP and then selectively removing the first oxide layer 19 and the first nitride layer 18 down to the surface of the first dielectric layer 14.

In FIG. 5, for each row line 13, an opening 20 is formed which extends at least in part over the row line 13. In particular, at least one vertical surface of each opening 20 (in the drawings, on the left) lies above a respective row line 13. Each opening 20 may extend across the whole respective row line 13 or across only a part thereof, in which case a plurality of openings 20 are aligned to each other along each row line 13. The openings 20 may have a substantially parallelepipedal shape in one embodiment.

Then, a spacer layer, e.g. of silicon nitride, is deposited and etched back to remove the horizontal portions of the spacer layer, leaving vertical spacers 21 extending along the vertical surfaces of the openings 20. These spacers 21 join the first nitride layer 18 at the bottom and form, with the first nitride layer 18, a protective region 22. Thus, the structure of FIG. 5 is obtained, wherein the protective region 22 together with the first oxide layer 19 form an encapsulating structure.

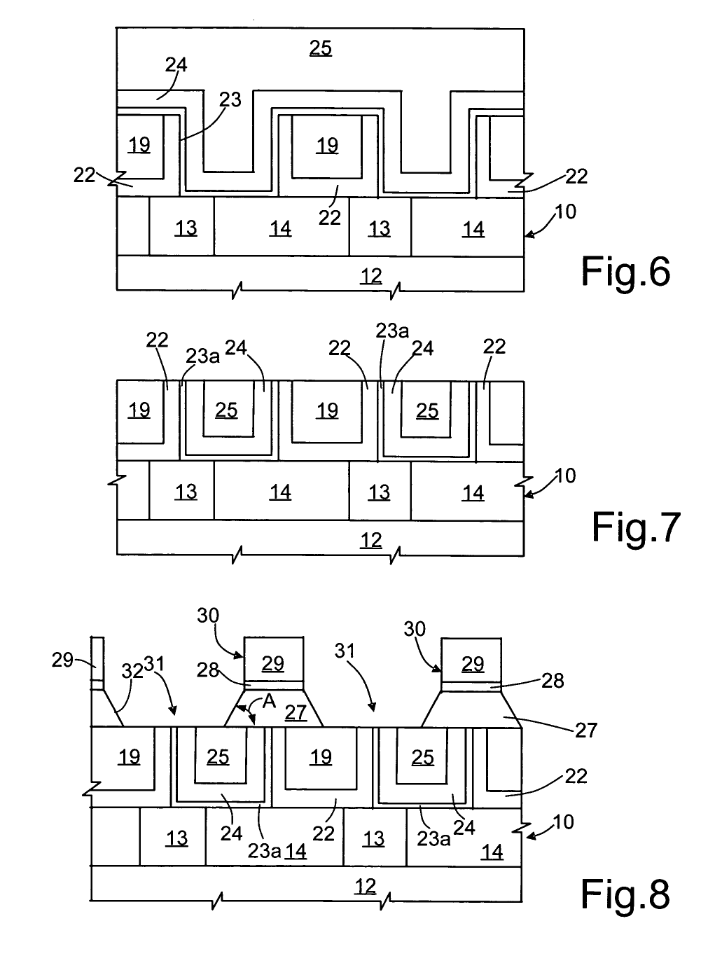

Thereafter, as shown in FIG. 6, a resistive layer 23 is deposited and stabilized. For example, TiSiN may be used, which conformally covers the bottom and the sides of the openings 20. Subsequently, a sheath layer 24, e.g. of silicon nitride, and a second oxide layer 25 are deposited. The second oxide layer 25 may be sub atmospheric chemical vapor deposition undoped silicon glass (SACVD USG), a high density plasma USG (HDP USG), or plasma enhanced chemical vapor deposition USG (PECVD USG) and completely fills the openings 20 to complete the encapsulating structure.

Here, the sheath layer 24 and the protective region 22 isolate the resistive layer 23 from the silicon oxide of the first and second oxide layers 19, 25 and prevent oxidation of the resistive layer 23.

The structure is then planarized by CMP, thus removing all portions of the second oxide layer 25, of the sheath layer 24 and of the resistive layer 23 above the openings 20, as shown in FIG. 7. In particular, the remaining portions of the resistive layer 23 form a plurality of cup-shaped regions 23a (one for each cell of the memory array).

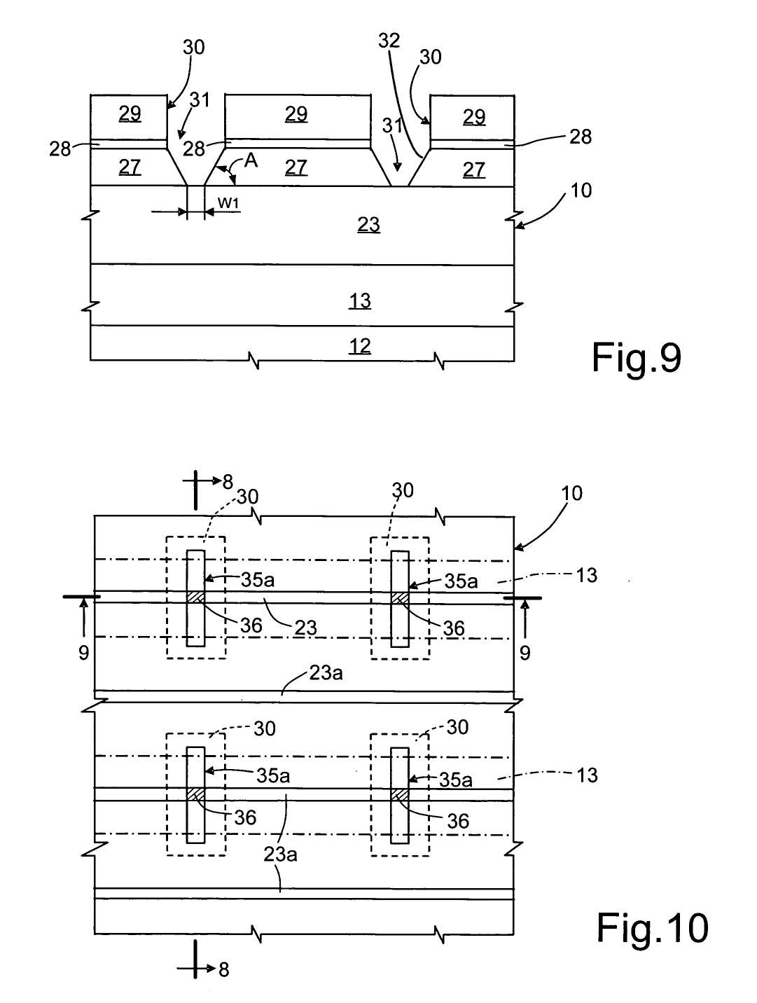

Then, as shown in FIG. 8, a mold layer 27, for example of nitride with a thickness of 10-100 nm, and an adhesion layer 28, for example of Ti or Si with a thickness of 1-10 nm, are deposited in sequence. Next, a photoresist mask 29 is formed. The photoresist mask 29 (see also FIGS. 9 and 10) has apertures 30 which expose portions of layers 27-28 that extend over one of the vertical side walls of the cup-shaped resistive regions 23a. The apertures 30, shown in FIG. 10, have a rectangular shape, with longer sides extending perpendicularly to the direction of the row lines 13 and to the direction of the resistive regions 23a, and smaller sides extending parallel to the row lines 13. The width of the apertures 30 (length of the shorter sides in the view of FIG. 10) may be about 45-130 nm, while the length of the apertures 30 (length of the longer sides in the view of FIG. 10) may be above 70-200 nm, respectively.

Subsequently, the adhesion layer 28 and the mold layer 27 are etched through the apertures 30, so as to open microtrenches 31. The exposed portion of the adhesion layer 28 is preliminarily removed and then the mold layer 27 is etched using a combined chemical and physical plasma etch. In particular, an etchant mixture of a boron halide, preferably BCl₃, and chlorine Cl₂ may be supplied to the wafer 10. The etchant mixture may comprise also a small amount of CHF₃, to increase the etching rate. For example, a suitable etchant mixture comprises 90% to 40% of BCl₃ (preferably 58%), 49% to 10% of Cl₂ (preferably 38%), and less than 10% of CHF₃ (preferably 4%).

Plasma containing BCl₃ is highly sputtering. Bonding inside the mold layer 27 (Si—N bonding, in this case) is weak enough to break up under ion bombarding with boron ions. Also, possible metallic residues of the adhesion layer 28 may be removed by sputtering. Moreover, the sputtering yield of BCl₃ depends on the impinging angle of the boron ions and is maximum at around 70°. So, under the prevailing sputtering regime of BCl₃, the etched portions of the mold layer 27 slope and tend to converge to that angle which maximizes the sputtering yield. In this condition, the greatest energy gain is achieved. Accordingly, the inclined walls 32 of the mold layer 27 and the wafer surface form an angle A which is close to the angle of maximum sputtering yield. More precisely, the angle A is about 60°-70° and also accounts for chemical etching, as explained hereinafter.

In fact, BCl₃ etches the mold layer 27 chemically as well. In particular, chemical etching rate of BCl₃ is rather low, however, enough to increase overall etching rate. Moreover, BCl₃ has a negligible polymerization rate, so that polymer deposition on the walls is substantially prevented. Cl₂ and CHF₃ further increase chemical etching rate.

The slope of the walls 32 of the microtrench 31 depends on both physical (sputtering) and chemical etching, as already explained; however, the profile of the microtrench 31 may be controlled primarily through the physical effect and secondarily through the chemical effect, since sputtering prevails. One advantageous slope of the walls 32 is about 65°.

Thereby, the microtrench 31 has a sublithographic bottom width W1 (FIG. 9) in a direction parallel to the row lines 13. W1 may be about 25-60 nm in one embodiment.

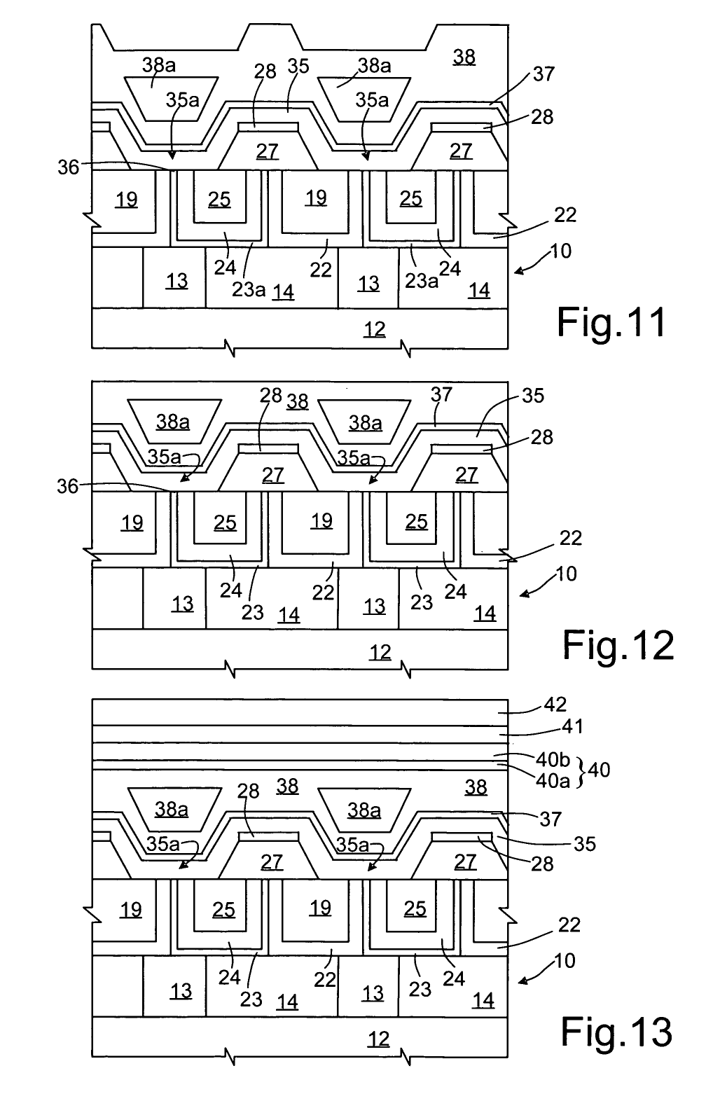

After removing the mask 29, an Ovonic Memory Switch/Ovonic Threshold Switch stack is deposited. A first first chalcogenic layer 35, for example of Ge₂Sb₂Te₅ with a thickness of 60 nm, is deposited conformally as shown in FIG. 11. A thin portion 35a (FIG. 12) of the chalcogenic layer 35 fills the microtrench 31 and forms, at the intersection with the resistive region 23a, a contact area 36.

Then, a barrier layer 37 (e.g., Ti/TiN) and a planarizing layer 38 (e.g., a metal layer, such as CVD TiN, TiSiN or other metal layer having planarizing features) are deposited. Deposition of the planarizing layer 38 may give rise to the formation of submerged keyholes 38a, as shown in the figures, however, these keyholes are not detrimental to the operation of the completed device.

Referring to FIG. 12, the wafer 10 is planarized (e.g. by CMP), and, as shown in FIG. 13, a bottom electrode layer 40 (preferably a double layer including a lower layer 40a e.g. of Ti and an upper layer 40b e.g. of TiAlN), a second chalcolgenic layer 41 (e.g., As₂Se₃) and a top electrode layer 42 (e.g., TiAlN) are deposited.

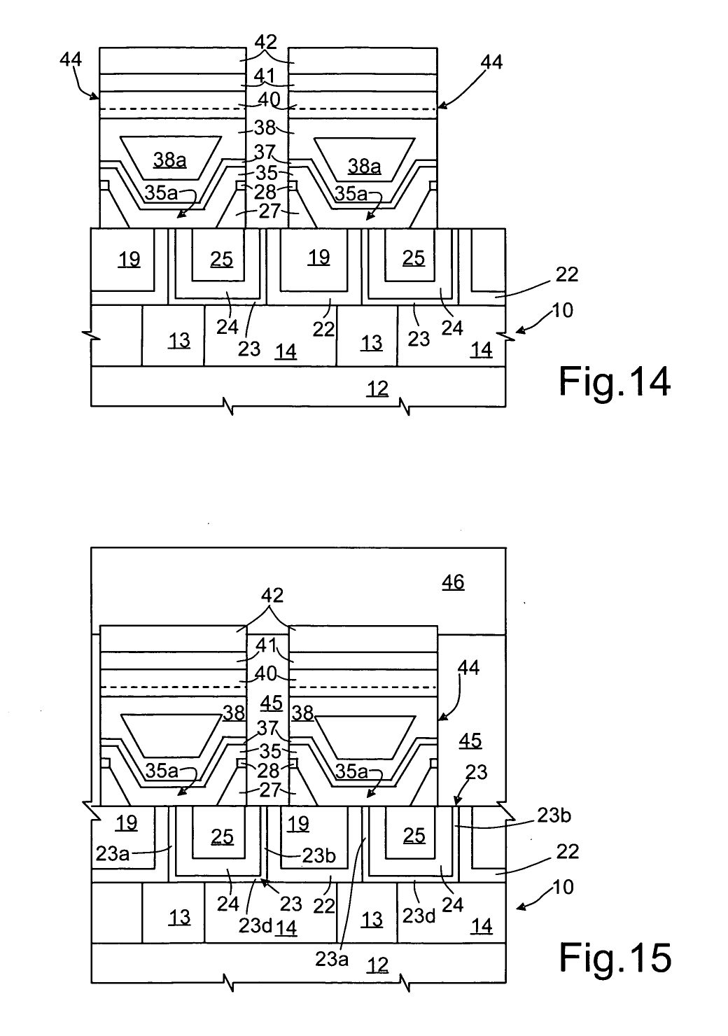

The stack of layers 42-40, 38, 37, 35, 28 and 27 is then patterned to form “dots” 44 (FIG. 14). FIG. 14 shows two stacks 44 which extend substantially aligned along a column of the array (see also FIG. 17).

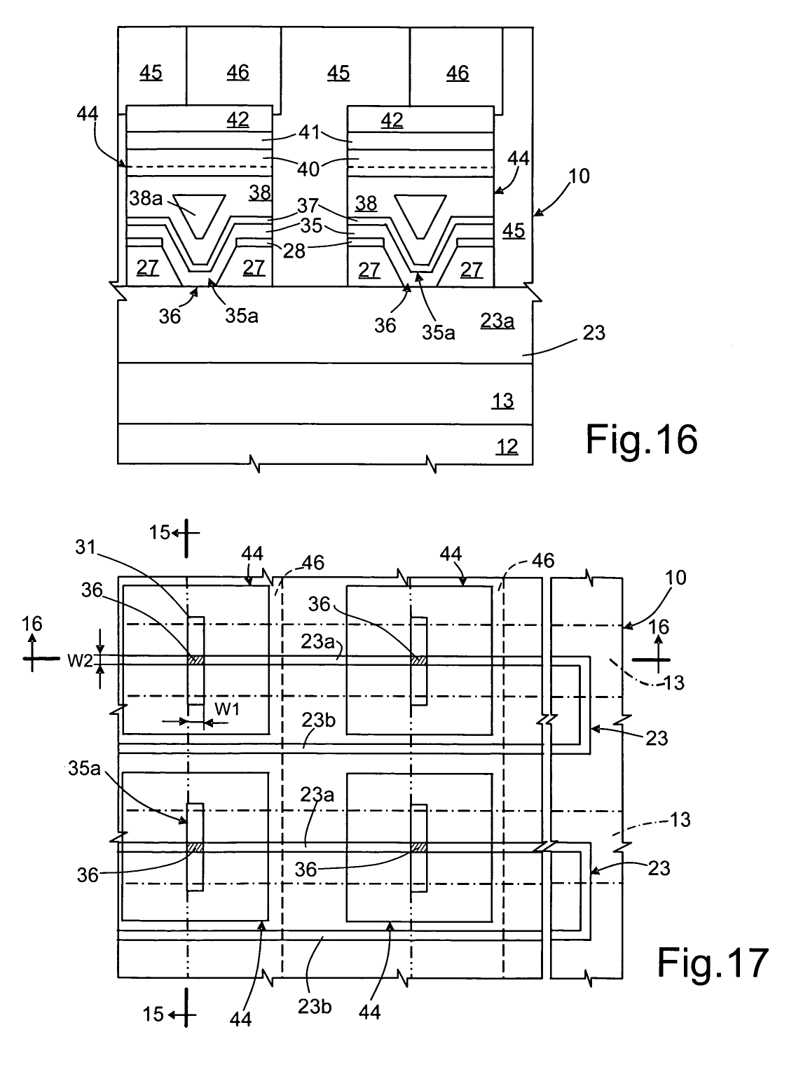

Then, a second insulating layer 45 (e.g. of silicon dioxide) is deposited, as shown in FIG. 15, and the wafer is subjected to CMP to planarize the structure. Finally, column lines and vias are formed, preferably using a standard dual damascene copper process. To this end, preferably the second insulating layer 45 is etched in a two-step process to form trenches extending down to the top of the dots 44 as well as vias openings (not shown), extending down to the row lines 13. Then, a metal material (e.g. Cu) is deposited that fills the trenches and vias, forming column lines 46 and row line connections (not shown). Column lines 46 correspond to the bit lines 5 of FIG. 1. Thus, each dot 44 is formed at the intersection between a row line 13 and a column line 46 as shown in FIGS. 15-17. Obviously, connections to the underlying circuitry may be provided by this metallization level, which is not necessarily the first one.

As shown in FIGS. 15-17, in the final structure, each resistive layer 23 has a substantially elongated, box-like shape with a U-shaped cross-section, corresponding to the shape of the respective opening 20. Specifically, each resistive layer 23 comprises a rectangular bottom region 23d and four vertical wall elements including a first and a second elongated wall elements 23a, 23b and two end wall elements 23c (only one visible in FIG. 17).

The first elongated wall element 23a (on the left, in the cross-section of FIG. 15) extends approximately above the midline of the respective row line 13 and is in electrical contact therewith; the second wall element 23b (on the right) extends on top of the first dielectric layer 14. Each first elongated wall element 23a forms a substantially rectangular wall-shaped resistive element that contacts the respective stack 44 along a line and is shared by all the stacks 44 aligned on a single row line 13, while the second wall element 23b has no electrical function. The electrical connection of all the stacks 44 along a same row line 13 through the respective first elongated wall element 23a does not impair the operation of the memory device, since the second chalcogenic region 41 of the stacks 44 forms an OTS or selection element allowing access to only the stack 44 connected to both the row line 13 and the column line 46 that are addressed.

As visible in FIGS. 15-17, each stack 44 comprises a mold region 27 delimiting a microtrench 31 having an elongated shape completely comprised in the area of the stack 44. The microtrench 31 extends perpendicularly to the first elongated wall element 23a, so that, in the embodiment shown, the contact area 36 is rectangular and has a width W2 given by the thickness of the resistive region 23a and a length W1 equal to the bottom width of the microtrench 31. Both these dimensions are sublithographic, as discussed above. In particular, it is possible to obtain both a very reduced cell area and a reduced contact area 37. Specifically it is possible to obtain a cell area of e.g., 4F²-6F², where F is the minimum lithographical dimension available for a given technology, e.g. 65-90 nm) and a reduced contact area 36 (W1×W2, wherein W1 is, e.g., 25-60 nm and W2 is, e.g., 1-10 nm).

Even if the microtrench 31 is not exactly perpendicular to the first elongated wall element 23a, and the contact area 36 is no more rectangular, it still has sublithographic dimensions.

The volume of the thin portion 35a of the first chalcogenic layer 35 that extends above the contact area 36 forms a phase change region intended to store information.

By virtue of the mold region 27, the memory region 35 has a bottom portion forming the thin portion 35a and a top portion extending on the mold region 27. An annular inclined portion of the memory region 35 extends along the tapered walls of the mold region 27 and connects the bottom and the top portion of the memory region 35.

Furthermore, each stack 44 comprises an adhesion layer 28 on the mold region 27, a first chalcogenic region 35, a barrier region 37, a planarizing region 38, a bottom electrode 40, a switching region 41 and a top electrode 42.

In some embodiments, the decoding elements may be accommodated in the substrate below the array, thus resulting in a considerable saving in the occupied area.

The described structure may be repeated more times on different levels, thus allowing the formation of stacked arrays, with a further reduction in the memory bulk.

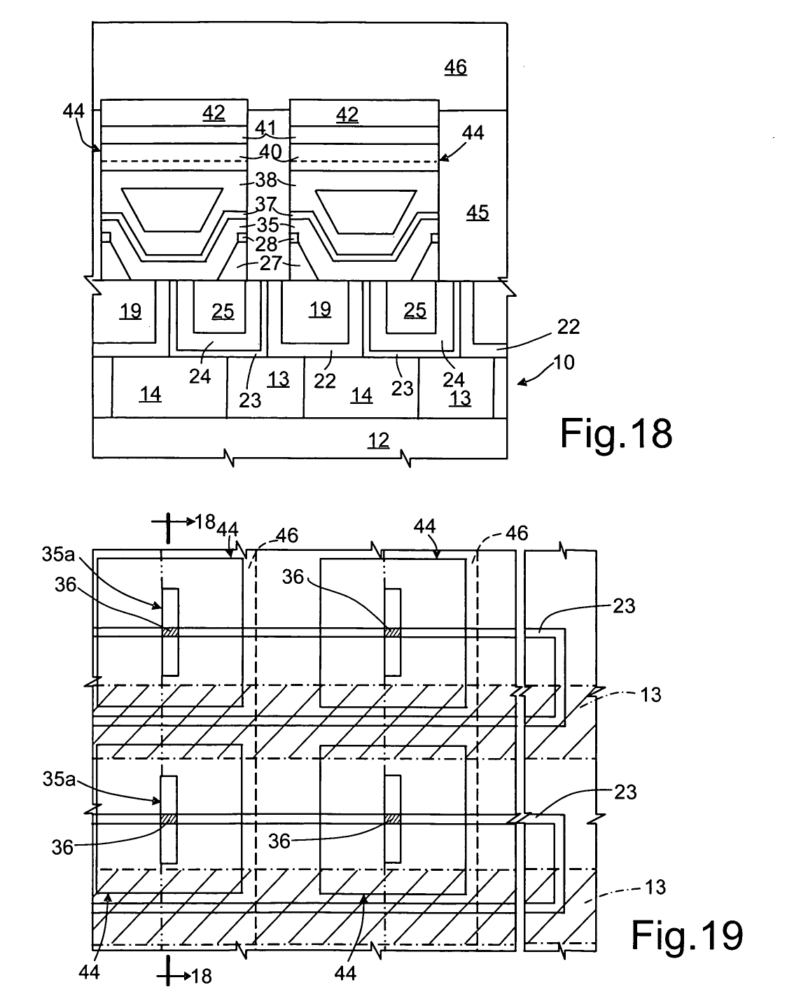

FIGS. 18-19 show a different embodiment of the invention, wherein the stacks 44 are not centered with respect to the respective row lines 13, but are offset so as to protrude partially with respect the respective row lines 13. In this case, the row lines 13 are connected to the respective resistive elements 23a through the bottom regions 23d of the layers 23.

This solution may, in some embodiments, afford an improved thermal isolation of the first chalcogenic regions 35, and in particular, the phase change portion thereof, from the respective row lines 13.

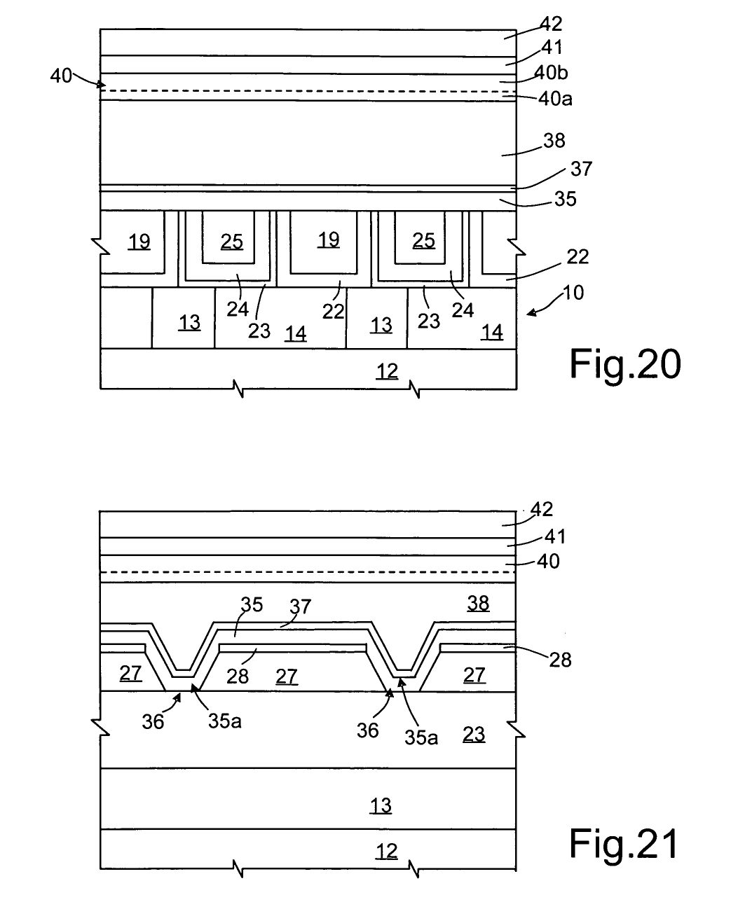

FIGS. 20-23 show another embodiment, wherein the microtrenches 31 extend along the whole column lines 42, or at least each microtrench 31 stretches over more than one cell.

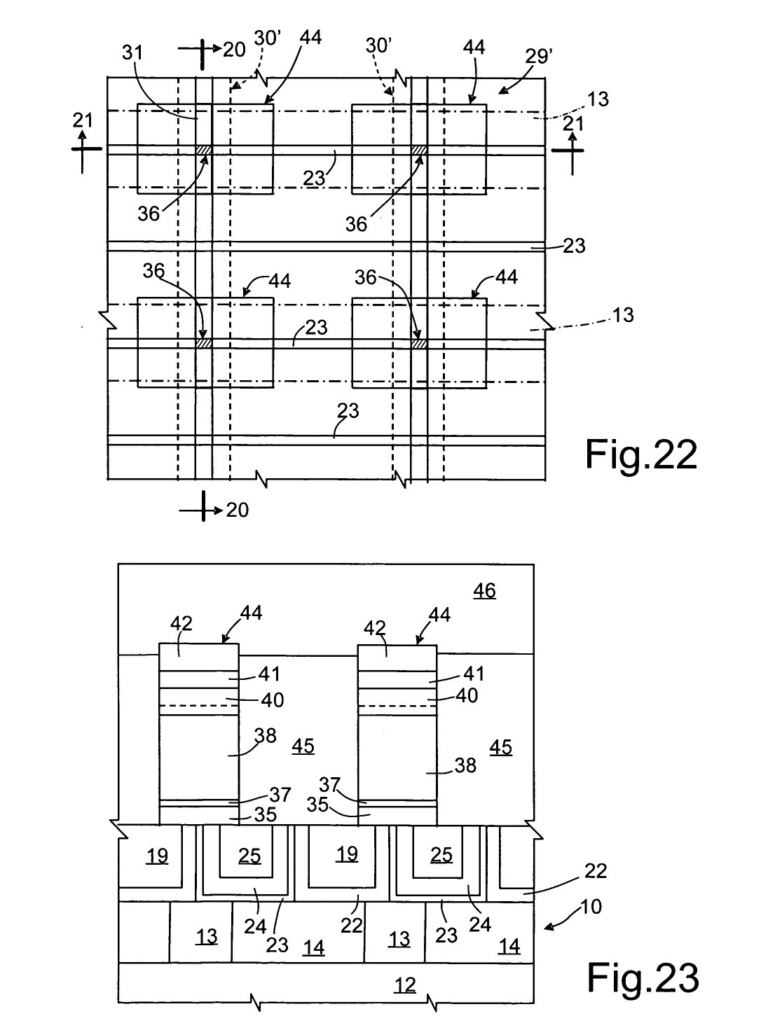

Reference is made to FIGS. 20-22, corresponding to the manufacturing step of FIG. 13 and wherein parts that are the same as in the embodiment of FIGS. 3-17 have been designed with the same reference numbers. The mold layer 27 and the adhesion layer 28 (FIG. 21) are defined using a mask 29′ having elongated openings 30′ (FIG. 22) so as to form elongated microtrenches 31′ with sloped walls in the mold layer 27. Thereby, in the cross-section of FIG. 20, the mold and adhesion layers 27, 28 are not visible since they have been removed in the areas between adjacent stacks (still to be formed). The mold layer 27 and the adhesion layer 28 are instead visible in the cross-section of FIG. 21.

Then, analogously to the embodiment of FIGS. 3-17, the first chalcogenic layer 35 is deposited conformally. Thereby, thin portions 35a of the chalcogenic layer 35 fill the elongated microtrenches 31′ and form, at the intersections with the resistive layers 23, the contact areas 36. Here, each thin portion 35a defines a plurality of contact areas 36 which are then isolated from each other during the stack definition step.

Thereafter, the barrier layer 37 (FIG. 20) and the planarizing layer 38 are deposited. In this case, the process parameters are studied to avoid the keyhole or to fill it, as explained later on; the wafer 10 is planarized, e.g. by CMP; a bottom electrode layer 40 (including lower layer 40a and upper layer 40b), the second chalcolgenic layer 41 and the top electrode layer 42 are deposited. Thus, the structure of FIGS. 20 and 21 is obtained.

Afterwards, the layers 42-40, 38, 37, 35, 28 and 27 is defined to form the stacks 44, whose shape is visible in FIG. 22. In FIG. 23, the second insulating layer 45 is deposited, the wafer 10 is subjected to CMP, and the column lines 46 and the vias (not visible) are formed.

According to this embodiment, after defining the stacks 44, each microtrench 31 extends for the whole width of the stack 44 (wherein the term width here denotes the dimension perpendicular to the row lines 13) so that in the cross-section of FIG. 23 the top portions of the first chalcogenic layer 35 are not visible.

With the alternative structure of FIGS. 20-23 it is possible to manufacture cells of smaller area in some embodiments. In particular, the stacks 44 may have a length (dimension in the direction parallel to the row lines 13) of 0.18-0.22 μm and a width (dimension in the direction perpendicular to the row lines 13) of about 0.18 μm; the stacks 44 may be separated, in the direction of the row lines 13, of about 0.16 μm and, in the direction perpendicular to the row lines 13, by about 0.16 μm.

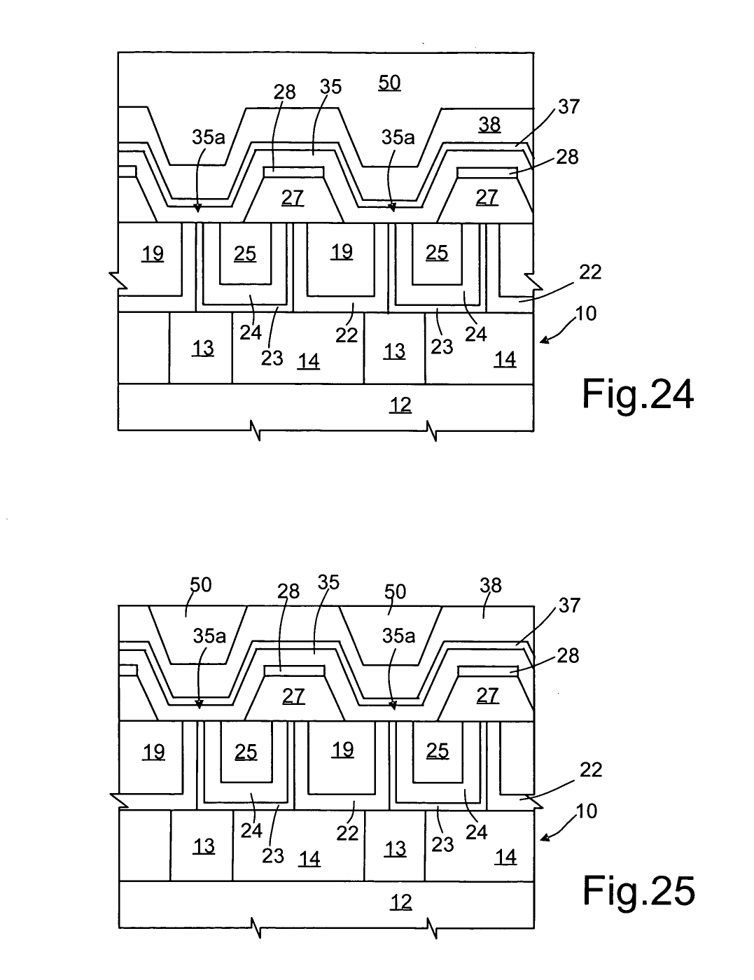

FIG. 24-27 show a different embodiment of the invention, using a different technique for planarizing the wafer. According to this embodiment, after depositing the barrier layer 37 (also here, e.g., of Ti/TiN) the planarizing layer 38 is deposited to avoid the formation of buried keyholes (e.g. for a thickness of 10-50 nm) as shown in FIG. 24. Then a third insulating layer 50 is deposited, for example by High Density Plasma (HDP) or Spin-On-Glass (SOG) deposition to completely fill the cavities of the planarizing layer 38.

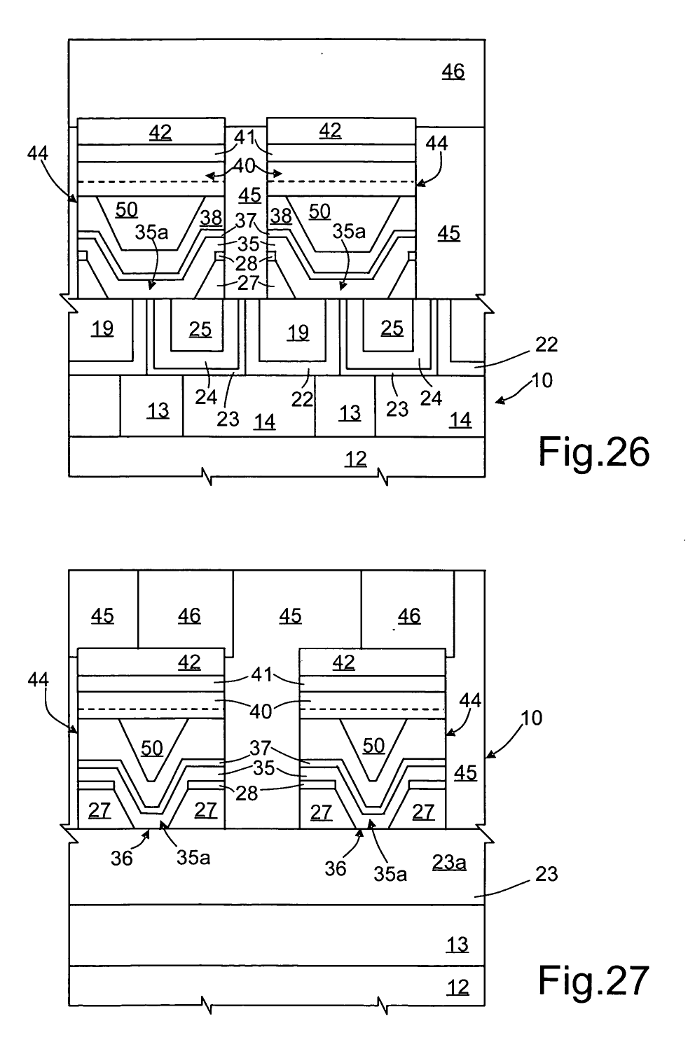

Then, the wafer 10 is planarized by CMP and planarization stops when reaching the metal material of the planarizing layer 38 (FIG. 25). Analogously to the first embodiment (see FIGS. 26 and 27) the bottom electrode layer 40, the second chalcolgenic layer 41 and the top electrode layer 42 are deposited; the stack of layers 42-40, 38, 37, 35, 28 and 27 is defined to form the dots 44; the second insulating layer 45 is deposited; the wafer 10 is subjected to CMP and the column lines 46 and the vias (not visible) are formed.

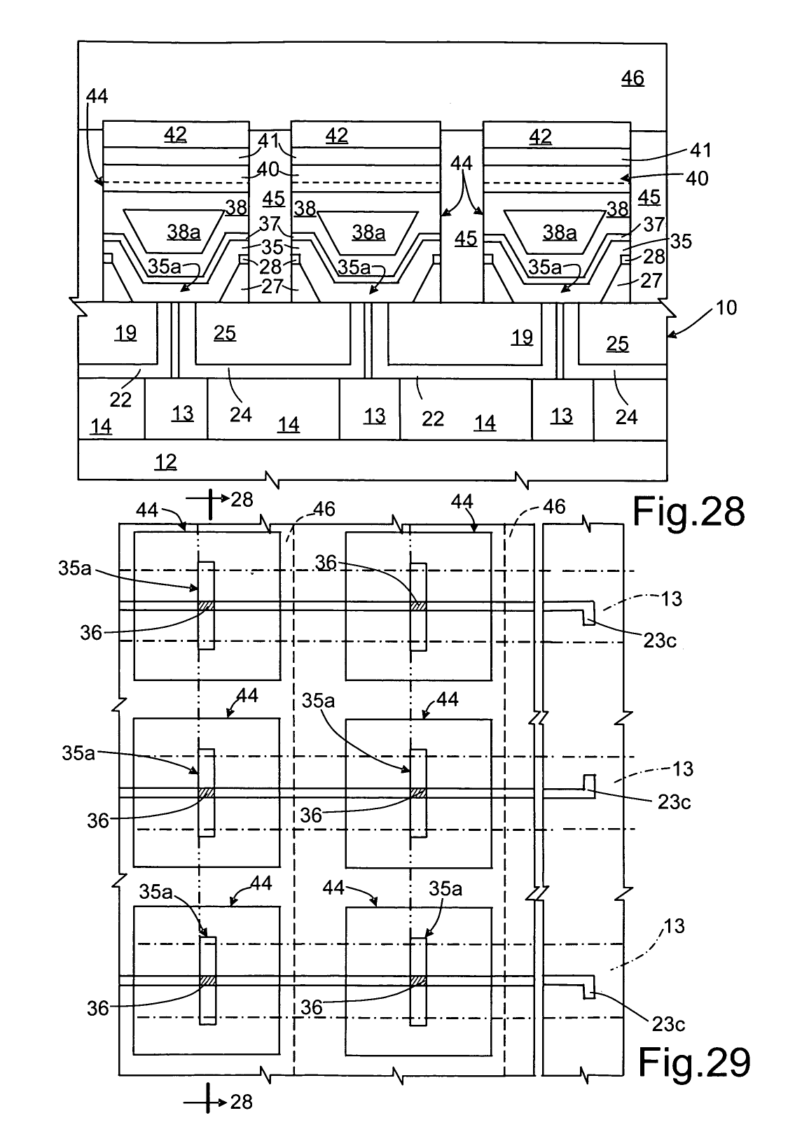

According to still another embodiment, the second wall element 23b (on the right in FIGS. 28, 29) may be used as a distinct resistive element. In this case, as visible from FIGS. 28, 29, the resistive layer 23 must be removed from the bottom of the openings 20 and the first and second elongated wall elements 23a, 23b must be electrically disconnected, in order to avoid electrical short between two adjacent row lines. To this end, as visible from the top view of FIG. 29 and evident with the comparison with FIG. 17, the end wall regions 23c of the resistive layer 23 are interrupted, e.g., by means of a specific etching step. In the alternative, the end wall regions 23c may be oxidized. The cross-section of the final structure is visible in FIG. 28.

The chalcogenic materials used may be varied from those disclosed herein which are only exemplary, and any chalcogenic material or mixture of materials, including multiple layers known in the art and suitable to store information depending on its physical state (for first chalcogenic layer 35) and to operate as a switch (for second chalcogenic layer 341) may be used. Moreover any barrier layer or mixture of barrier layers suitable to separate and seal chalcogenic materials may be used, such as carbon, which may provide better endurance and more stable operating characteristics such as threshold current, voltage, and leakage.

The microtrenches 31a with sloped walls create a small contact area 36. However, it is possible to form trenches in the mold layer 27 with substantially vertical walls. If desired, it is also possible to remove the top portion of the first chalcogenic layer 35, leaving only the thin portion 35a.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A phase change memory comprising:
an insulating material;
a trench formed in said insulating material, said trench having inclined sidewalls; and
a phase change material in said trench.

2. The memory of claim 1 including a wall heater to heat said material

3. The memory of claim 2 wherein said wall heater is U-shaped including a base and an upstanding wall extending therefrom.

4. The memory of claim 3 wherein said wall heater includes an upper edge defining a closed geometric shape.

5. The memory of claim 4 wherein said upper edge of said wall contacts said phase change material.

6. The memory of claim 5 wherein only a portion of the upper edge of said wall contacts said phase change material.

7. The memory of claim 6 wherein said wall heater is misaligned with said phase change material.

8. The memory of claim 1 wherein said trench has four inclined sidewalls.

9. The memory of claim 8 wherein said sidewalls are at an angle of about 60 to about 70 degrees to the horizontal plane.

10. The memory of claim 2 wherein said trench is elongated in a first direction and said wall heater extends orthogonally to said first direction.

11. A method comprising:
forming a dielectric layer;
forming a trench in said dielectric layer having inclined sidewalls; and
forming a phase change material in said trench.

12. The method of claim 11 wherein prior to forming said dielectric material, a wall heater is formed and said dielectric material is formed over said wall heater.

13. The method of claim 12 including forming said wall heater in a U-shape having a base and an upstanding wall extending therefrom.

14. The method of claim 13 including forming said wall heater with an upper edge defining a closed geometric shape.

15. The method of claim 14 including forming said upper edge in contact with said phase change material.

16. The method of claim 15 including contacting only a portion of said upper edge of said wall with said phase change material.

17. The method of claim 16 including misaligning said wall heater with said phase change material.

18. The method of claim 11 including forming said trench with four inclined sidewalls.

19. The method of claim 18 including forming said sidewalls at an angle of about 60 to about 70 degrees to the horizontal plane.

20. The method of claim 12 including forming said trench elongated in a first direction and forming said wall heater to extend orthogonally to said first direction.
